(19) United States
(12) Patent Application Publication
(10) Pub. No.: US 2017/0231100 A1
(43) Pub. Date: Aug. 10, 2017

(54) CIRCUIT BOARD STRUCTURE AND METHOD FOR MANUFACTURING THE SAME

(71) Applicant: ICHIA TECHNOLOGIES,INC., Taoyuan City (TW)

(72) Inventors: Yung-Hsiang SUN, Taoyuan City (TW); Qin CHEN, Suzhou (CN)

(21) Appl. No.: 15/155,349

(22) Filed: May 16, 2016

(30) Foreign Application Priority Data
Feb. 4, 2016 (CN) 201610079405.8

(51) Int. Cl. H05K 3/46; H05K 3/22; H05K 1/02

(52) U.S. Cl. CPC H05K 3/4644; H05K 1/0298; H05K 3/4611; H05K 3/22; H05K 2203/10; H05K 2201/0183

(57) ABSTRACT

A circuit board structure includes a circuit board and an adhesive layer. The circuit board has a first board surface and an opposite second board surface, and the first board surface defines a predetermined portion. The circuit board has a conductive circuit disposed on the first board surface and at least partially arranged on the predetermined portion. The adhesive layer is seamlessly formed on the predetermined portion of the first board surface of the circuit board, and the conductive circuit arranged on the predetermined portion is seamlessly covered by the adhesive layer. A surface of the adhesive layer arranged away from the circuit board is a planar bonding surface.

### BACKGROUND OF THE INVENTION

1. Field of the Invention

The instant invention relates to a circuit board; in particular, to a circuit board structure and a method for manufacturing the same.

2. Description of Related Art

Please refer to FIGS. 1 and 2, which show a conventional circuit board structure 100′. The conventional circuit board structure 100′ is prepared by removing a release film (not shown) of a double sided tape 2′ and then adhering the double sided tape 2′ to a circuit board 1′. The double sided tape 2′ is disposed on the conductive circuit 11′ of the circuit board 1′. Accordingly, the double sided tape 2′ can be used to adhere the circuit board 1′ to a predetermined surface by removing another release film 3′.

However, the circuit board 1′ and the double sided tape 2′ are manufactured respectively by two independent producing processes and are manufactured respectively by two different manufacturers, so the producing cost of the conventional circuit board structure 100′ can be further reduced. Moreover, before the double sided tape 2′ is adhered to the circuit board 1′, a larger double sided tape must be cut according to the shape of the circuit board 1′ so as to form the double sided tape 2′, but the cutting step causes material waste. Moreover, the manufacturer needs to implement an adhering step to combine the double sided tape 2′ and the circuit board 1′.

Specifically, as shown in FIG. 3, the board surface 12′ of the circuit board 1′ has a specific roughness, so a plurality of gaps G exist between the double sided tape 2′ and the board surface 12′ and between the double sided tape 2′ and the conductive circuit 11′. Thus, the adhesion strength of the double sided tape 2′ and the circuit board 1′ needs to be improved.

### SUMMARY OF THE INVENTION

The instant disclosure provides a circuit board structure and a method for manufacturing the same, thereby effectively solving the problem generated by the conventional circuit board structure.

The instant disclosure provides a method for manufacturing a circuit board structure, comprising: a) providing a circuit board, wherein the circuit board has a first board surface and an opposite second board surface, the first board surface defines a predetermined portion; b) disposing the circuit board in a production apparatus; c) screen printing a pressure-sensitive gel on the predetermined portion of the circuit board to form a pressure-sensitive gel layer by using the production apparatus, wherein a thickness of the pressure-sensitive gel layer is 30 μm-350 μm; and d) solidifying the pressure-sensitive gel layer to form an adhesive layer seamlessly covering the predetermined portion of the circuit board by using the production apparatus, wherein a surface of the adhesive layer arranged away from the circuit board is defined as a bonding surface.

Preferably, the pressure-sensitive gel layer is a UV-curable pressure-sensitive gel layer; the method further comprises: in the step d), solidifying the pressure-sensitive gel layer to form the adhesive layer by using UV light emitted from the production apparatus; and after the step d), disposing a release film on the bonding surface of the adhesive layer.

Preferably, the pressure-sensitive gel layer is a UV-curable pressure-sensitive gel layer; the method further comprises: after the step c), disposing a transparent release film on a surface of the pressure-sensitive gel layer arranged away from the circuit board; and in the step d), solidifying the pressure-sensitive gel layer to form the adhesive layer by using UV light emitted from the production apparatus to pass through the transparent release film.

The instant disclosure also provides a circuit board structure, comprising: a circuit board having a first board surface and an opposite second board surface, wherein the first board surface defines a predetermined portion, the circuit board has a conductive circuit disposed on the first board surface, and at least part of the conductive circuit is disposed on the predetermined portion; and an adhesive layer seamlessly formed on the predetermined portion of the first board surface of the circuit board, wherein the adhesive layer seamlessly covers the at least part of the conductive circuit, and a surface of the adhesive layer arranged away from the circuit board is a planar bonding surface.

In summary, the method of the instant disclosure is directly and integrally forming the adhesive layer on the circuit board, so a single manufacturer can independently produce the circuit board structure without the conventional adhering step and the conventional cutting step of the double sided tape, thereby effectively reducing the producing cost of the circuit board structure.

Moreover, the pressure-sensitive gel layer is seamlessly formed on the board surface of the circuit board, so no gap exists between the adhesive layer and the circuit board, and the adhesion strength of the adhesive layer and the circuit board can be increased by the roughness of the board surface of the circuit board.

In order to further appreciate the characteristics and technical contents of the instant invention, references are hereunder made to the detailed descriptions and appended drawings in connection with the instant invention. However, the appended drawings are merely shown for exemplary purposes, rather than being used to restrict the scope of the instant invention.

### BRIEF DESCRIPTION OF THE DRAWINGS

FIG. 1 is a cross-sectional view showing a conventional method for manufacturing a conventional circuit board structure;

FIG. 2 is a cross-sectional view showing the conventional circuit board structure;

FIG. 3 is an enlarged view showing the A portion of FIG. 2;

FIG. 4 is a cross-sectional view showing the steps a) and b) of a method for manufacturing a circuit board structure according to a first embodiment of the instant disclosure;

FIG. 5 is a cross-sectional view showing the step c) of the method according to the first embodiment;

FIG. 6 is a cross-sectional view showing the step d) of the method according to the first embodiment;

FIG. 7 is a cross-sectional view showing the step e) of the method according to the first embodiment;

FIG. 8 is an enlarged view showing the B portion of FIG. 7;

FIG. 9 is a cross-sectional view showing a variation in the steps of the method;

FIG. 10 is a cross-sectional view showing the steps a) and b) of a method for manufacturing a circuit board structure according to a second embodiment of the instant disclosure;

FIG. 11 is a cross-sectional view showing the step c) of the method according to the second embodiment;

FIG. 12 is a cross-sectional view showing the step d) of the method according to the second embodiment; and

FIG. 13 is a cross-sectional view showing the step e) of the method according to the second embodiment.

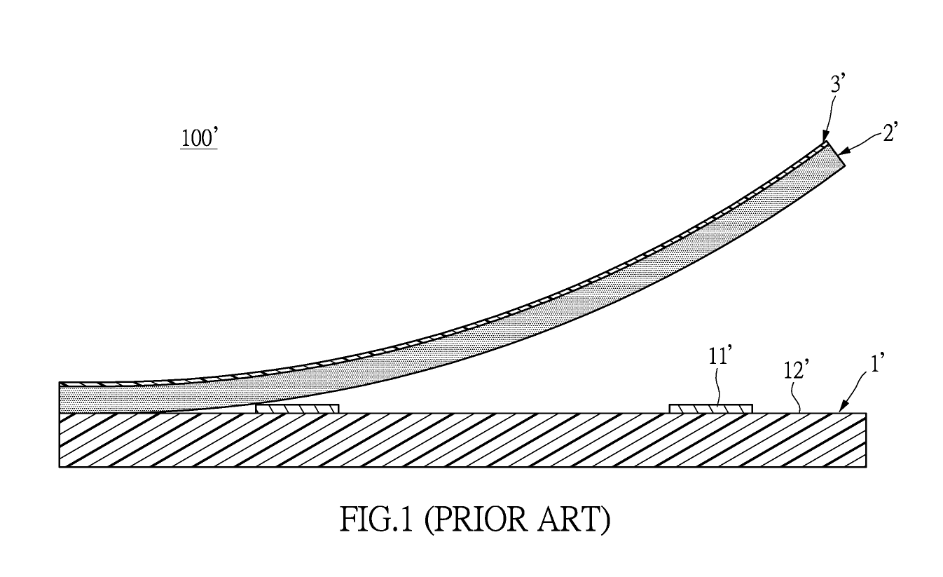

### DETAILED DESCRIPTION OF THE PREFERRED EMBODIMENTS

### First Embodiment

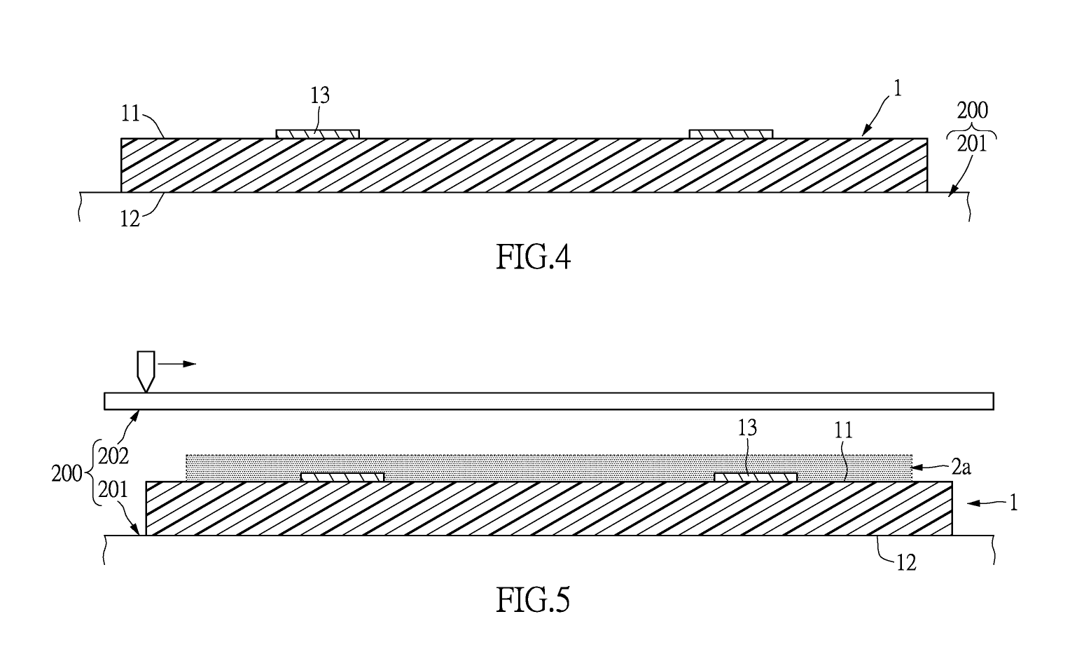

Please refer to FIGS. 4 through 8, which show a first embodiment of the instant disclosure. References are hereunder made to the detailed descriptions and appended drawings in connection with the instant invention. However, the appended drawings are merely shown for exemplary purposes, rather than being used to restrict the scope of the instant invention.

The instant disclosure provides a method for manufacturing a circuit board structure 100. The method includes steps a) to e), and the sequence of the steps of the method is disclosed for clearly understanding the instant embodiment, but the instant disclosure is not limited thereto. The steps of the method are disclosed as follows.

In step a), as shown in FIG. 4, a circuit board 1 is provided, and the circuit board 1 is preferably a flexible circuit board or a rigid-flex circuit board, but the circuit board 1 is not limited thereto. The circuit board 1 has a first board surface 11 (e.g., the top surface of the circuit board 1 shown in FIG. 4) and an opposite second board surface 12 (the bottom surface of the circuit board 1 shown in FIG. 4). The circuit board 1 has at least one conductive circuit 13 disposed on the first board surface 11. The first board surface 11 defines a predetermined portion (not labeled), and at least part of the conductive circuit 13 is disposed on the predetermined portion.

Specifically, the predetermined portion can be changed according to a designer's demand or the shape of the conductive circuit 13, and the predetermined portion in the instant embodiment is the center portion of the first board surface 11, but the predetermined portion is not limited thereto.

In step b), as shown in FIG. 4, the circuit board 1 is disposed in a production apparatus 200. Specifically, the second board surface 12 of the circuit board 1 is disposed on a table 201 of the production apparatus 200. The construction of the production apparatus 200 is complex, so the figures simply show the most basic production apparatus 200.

In step c), as shown in FIG. 5, the production apparatus 200 screen prints a pressure-sensitive gel (not labeled) on the predetermined portion of the circuit board 1 to seamlessly cover the predetermined portion by using a screen printing assembly 202 (e.g., scraper cooperated with one of a steel plate, nylon plate, steel mesh, or printing fixture), and the pressure-sensitive gel is formed to be a pressure-sensitive gel layer 2a having a thickness of 30 μm-350 μm. The pressure-sensitive gel layer 2a covers the conductive circuit 13 disposed on the predetermined portion, and a surface of the pressure-sensitive gel layer 2a arranged away from the circuit board 1 (i.e., the top surface of the pressure-sensitive gel layer 2a shown in FIG. 5) is a plane. Moreover, the thickness of the pressure-sensitive gel layer 2a can be adjusted according to a designer's demand, and the thickness of the pressure-sensitive gel layer 2a in the instant embodiment is preferably 100 μm-200 μm.

Specifically, the pressure-sensitive gel layer 2a can be a heat-curable pressure-sensitive gel layer or a light-curable pressure-sensitive gel layer. The pressure-sensitive gel layer 2a in the instant embodiment is a UV light-curable pressure-sensitive gel layer, but the pressure-sensitive gel layer 2a is not limited thereto. Moreover, the pressure-sensitive gel layer 2a can be made of acrylic, acrylates, silicone prepolymer, silicone monomer, or a mixture of silicone prepolymer and silicone monomer.

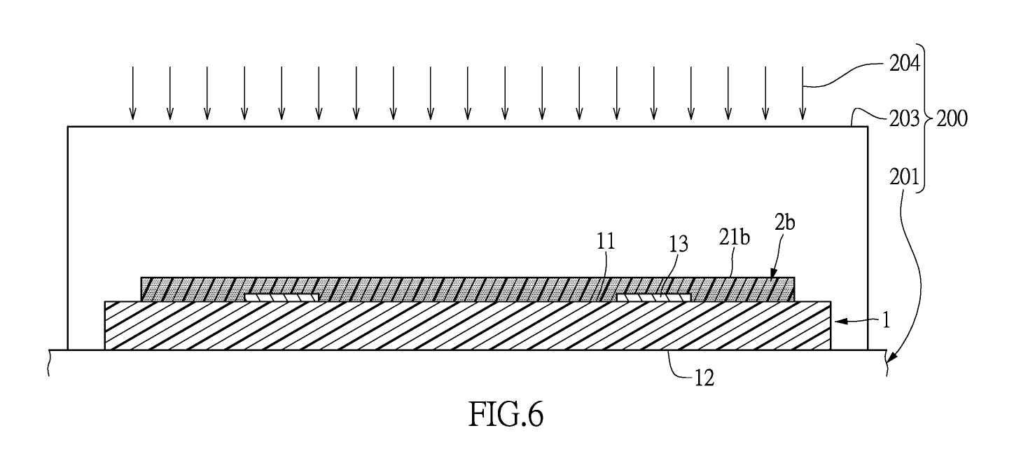

In step d), as shown in FIG. 6, the production apparatus 200 solidifies the pressure-sensitive gel layer 2a to form an adhesive layer 2b, and a surface of the adhesive layer 2b arranged away from the circuit board 1 (i.e., the top surface of the adhesive layer 2b shown in FIG. 6) is defined as a bonding surface 21b. The thickness of adhesive layer 2b is substantially equal to that of the pressure-sensitive gel layer 2a, and the bonding surface 21b of the adhesive layer 2b is a plane. That is to say, the bonding surface 21b of the adhesive layer 2b is approximately parallel to the first board surface 11 or the second board surface 12. Moreover, the adhesive layer 2b seamlessly covers the predetermined portion of the first board surface 11 of the circuit board 1 and the conductive circuit 13 (as shown in FIG. 8).

Specifically, the circuit board 1 and the pressure-sensitive gel layer 2a are disposed into a translucent chamber 203 of the production apparatus 200, and the production apparatus 200 is preferably filling or blowing nitrogen into the chamber 203 to make the chamber 203 be in a non-oxygen mode (e.g., an oxygen concentration of the chamber 203 is smaller than 100 ppm for achieving a preferable solidifying condition of the pressure-sensitive gel layer 2a). Accordingly, the production apparatus 200 solidifies the pressure-sensitive gel layer 2a by using UV light to pass through the chamber 203 for about 5-15 min.

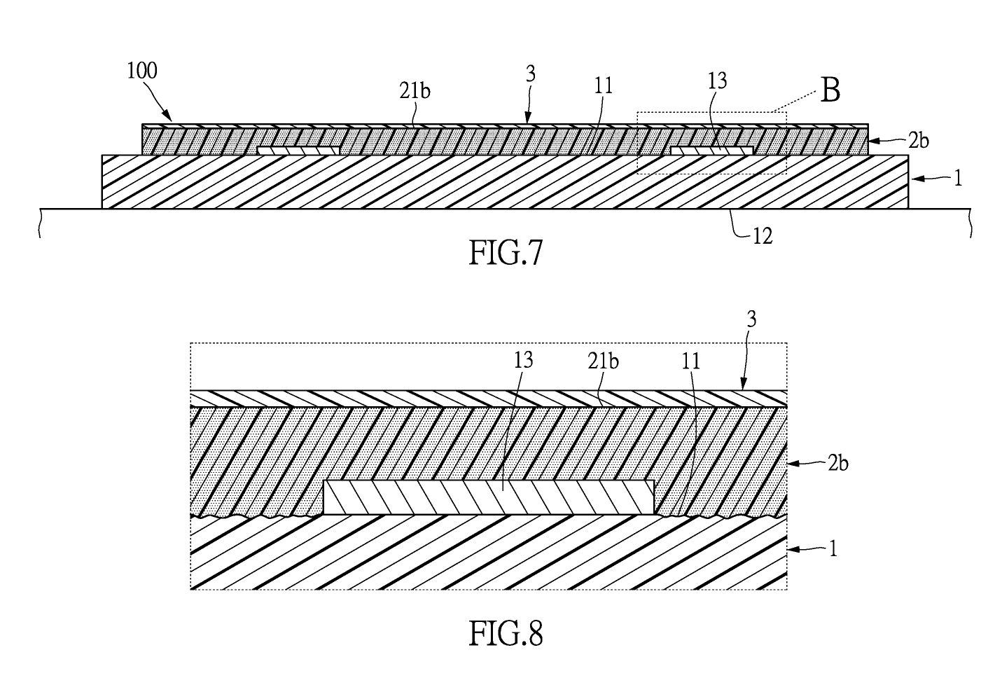

In step e), as shown in FIGS. 7 and 8, a release film 3 is flatly and detachably disposed on the bonding surface 21b of the adhesive layer 2b. Specifically, the release film 3 is approximately parallel to the first board surface 11 or the second board surface 12 (as shown in FIG. 7), and the release film 3 is entirely adhered to the bonding surface 21b of the adhesive layer 2b. In such a manner the circuit board structure 100 is prepared by the above steps of the method.

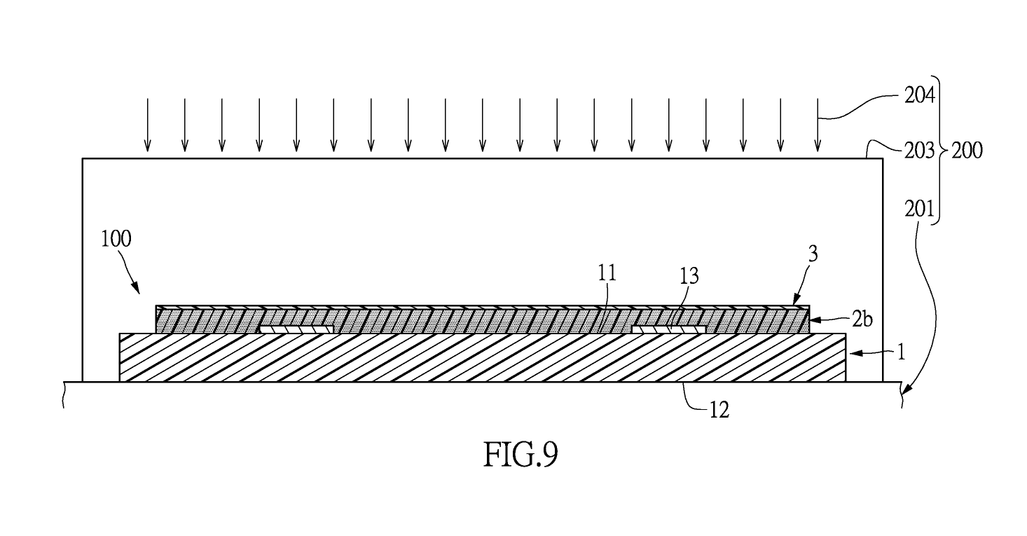

In addition, the instant disclosure is not limited the sequence of the steps a)-e). For example, as shown in FIG. 9, after the step c), a transparent release film 3 can be disposed on a surface of the pressure-sensitive gel layer 2a arranged away from the circuit board 1; in the step d), the production apparatus 200 solidifies the pressure-sensitive gel layer 2a to form the adhesive layer 2b by using UV light to pass through the chamber 203 and the transparent release film 3. Moreover, in a non-shown embodiment, the adhesive layer 2b can be formed on a board surface of the circuit board 1, which is provided without any conductive circuit 13; or two opposite board surfaces of the circuit board 1 are respectively provided with two adhesive layers 2b.

The method of the instant embodiment is directly and integrally forming the adhesive layer 2b on the circuit board 1, so a single manufacturer can independently produce the circuit board structure 100 without the conventional adhering step and the conventional cutting step of the double sided tape 2′, thereby effectively reducing the producing cost of the circuit board structure 100.

Moreover, the pressure-sensitive gel layer 2a is seamlessly formed on the board surface of the circuit board 1, so no gap exists between the adhesive layer 2b and the circuit board 1, and the adhesion strength of the adhesive layer 2b and the circuit board 1 can be increased by the roughness of the board surface of the circuit board 1.

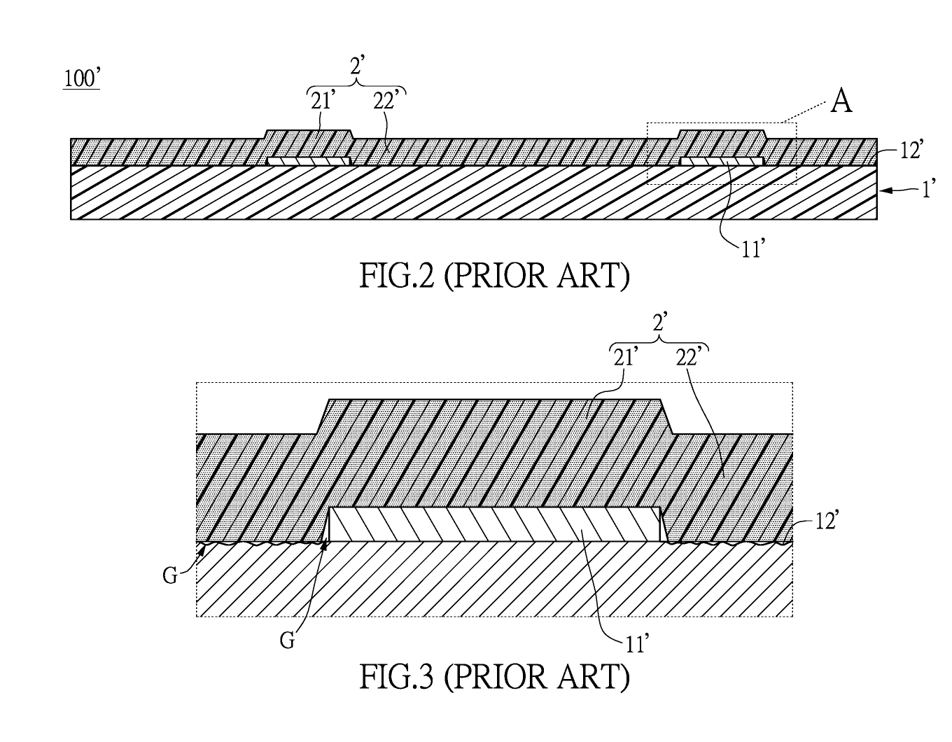

In other words, as shown FIGS. 2 and 3, the double sided tape 2′ of the conventional circuit board structure 100′ has at least one protruding portion 21′ and at least one planar portion 22′, the protruding portion 21′ is disposed on the conductive circuit 11′ and the planar portion 22′ is arranged around the conductive circuit 11′. Thus, the bonding surface of the double sided tape 2′ (e.g., the top surface of the double sided tape 2′ shown in FIG. 2) is not a flat surface, so the adhering force of the double sided tape 2′ can be improved. Specifically, when the conventional circuit board structure 100′ is adhered to a planar surface, the bonding surface of the double sided tape 2′ cannot have a uniform adhering force because the protruding portion 21′ is protruded from the planar portion 22′, such that the conventional circuit board structure 100′ is easily separated from the planar surface.

However, the method of the instant embodiment is directly and integrally forming the adhesive layer 2b on the circuit board 1 to obtain the planar bonding surface 21b, thereby increasing the adhering force of the adhesive layer 2.

The above description discloses the method of the instant disclosure, and the instant embodiment further provides a circuit board structure 100 prepared by implementing the method, but the circuit board structure 100 of the instant disclosure is not limited to the method. Moreover, the following description discloses the construction of the circuit board structure 100 for clearly understanding the circuit board structure 100.

As shown in FIGS. 7 and 8, the circuit board structure 100 includes a circuit board 1, an adhesive layer 2, and a release film 3 The circuit board 1 has a first board surface 11 and an opposite second board surface 12. The first board surface 11 defines a predetermined portion (not labeled), and the predetermined portion in the instant embodiment is the center portion of the first board surface 11. The circuit board 1 includes a conductive circuit 13 formed on the first board surface 11, and at least part of the conductive circuit 13 is formed on the predetermined portion.

The adhesive layer 2b is seamlessly and integrally formed on the predetermined portion of the first board surface 11 of the circuit board 1, and the conductive circuit 13 formed on the predetermined portion is seamlessly covered by the adhesive layer 2b, thereby increasing the adhesion strength of the adhesive layer 2b and the circuit board 1. A surface of the adhesive layer 2b arranged away from the circuit board 1 is a planar bonding surface 21. The adhesive layer 2b in the instant embodiment is made of acrylic, acrylates, silicone prepolymer, silicone monomer, or a mixture of silicone prepolymer and silicone monomer. The thickness of the adhesive layer 2b is 30 μm-350 μm, and is preferably 100 μm-200 μm.

The release film 3 is preferably a transparent film, but is not limited thereto. The release film 3 is seamlessly and detachably disposed on the bonding surface 21b of the adhesive layer 2b. Thus, the adhesive layer 2b and the release film 3 are provided with a better adhesion strength therebetween by forming the planar bonding surface 21b.

### Second Embodiment

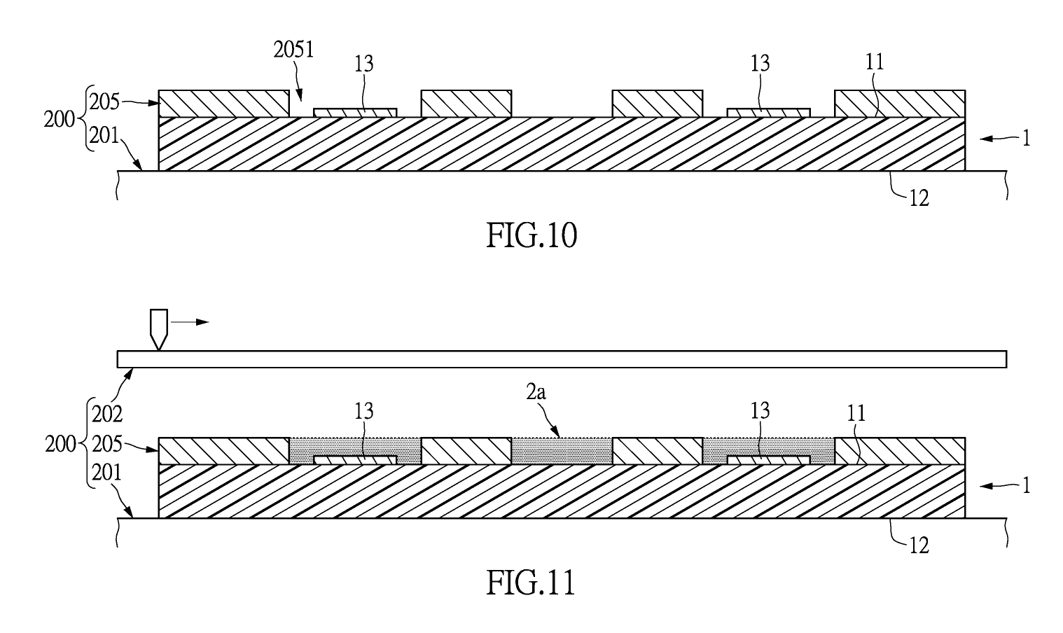

Please refer to FIGS. 10 through 13, which show a second embodiment of the instant disclosure. The instant embodiment is similar to the first embodiment, and the same features are not disclosed again. The main difference between the two embodiments is disclosed in the following description.

In step a), as shown in FIG. 10, a circuit board 1 is provided, and the circuit board 1 is preferably a flexible circuit board or a rigid-flex circuit board, but the circuit board 1 is not limited thereto. The circuit board 1 has a first board surface 11 and an opposite second board surface 12. The circuit board 1 has at least one conductive circuit 13 disposed on the first board surface 11. The first board surface 11 defines a predetermined portion (not labeled), and at least part of the conductive circuit 13 is disposed on the predetermined portion.

Specifically, the predetermined portion can be changed according to a designer's demand or the shape of the conductive circuit 13.

In step b), as shown in FIG. 10, the circuit board 1 is disposed in a production apparatus 200. Specifically, the second board surface 12 of the circuit board 1 is disposed on a table 201 of the production apparatus 200. The construction of the production apparatus 200 is complex, so the figures simply show the most basic production apparatus 200.

Moreover, a periphery fixture 205 is disposed on the first board surface 11, and the periphery fixture 205 has a patterned penetrating hole 2051. The penetrating hole 2051 is corresponding in position to the predetermined portion of the first board surface 11, and the conductive circuit 13 is arranged in the penetrating hole 2051.

In step c), as shown in FIG. 11, the production apparatus 200 screen prints a pressure-sensitive gel (not labeled) on the predetermined portion of the circuit board 1 (e.g., the pressure-sensitive gel is filled in the penetrating hole 2051 of the periphery fixture 205) to seamlessly cover the predetermined portion by using a screen printing assembly 202 (e.g., scraper cooperated with one of a steel plate, nylon plate, steel mesh, or printing fixture), and the pressure-sensitive gel is formed to be a pressure-sensitive gel layer 2a having a thickness of 30 μm-350 μm. The pressure-sensitive gel layer 2a covers the conductive circuit 13 arranged in the penetrating hole 2051, and a surface of the pressure-sensitive gel layer 2a arranged away from the circuit board 1 is a plane. Moreover, the thickness of the pressure-sensitive gel layer 2a can be adjusted according to a designer's demand, and the thickness of the pressure-sensitive gel layer 2a in the instant embodiment is preferably 100 μm-200 μm.

Specifically, the pressure-sensitive gel layer 2a in the instant embodiment is a UV light-curable pressure-sensitive gel layer, but the pressure-sensitive gel layer 2a is not limited thereto. Moreover, the pressure-sensitive gel layer 2a can be made of acrylic, acrylates, silicone prepolymer, silicone monomer, or a mixture of silicone prepolymer and silicone monomer.

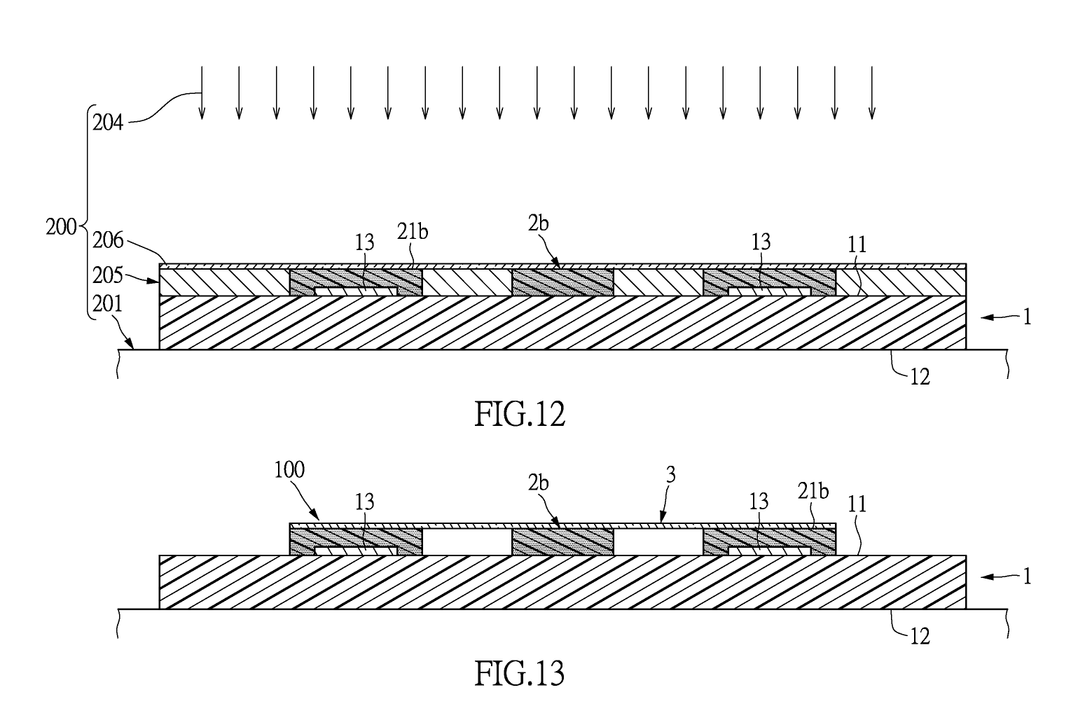

In step d), as shown in FIG. 12, a transparent film 206 is disposed on the pressure-sensitive gel layer 2a and the periphery fixture 205 for isolating the pressure-sensitive gel layer 2a from oxygen; and then, the pressure-sensitive gel layer 2a is solidified to form an adhesive layer 2b by using UV light to pass through the transparent film 206. A surface of the adhesive layer 2b arranged away from the circuit board 1 is a planar bonding surface 21b. The thickness of adhesive layer 2b is substantially equal to that of the pressure-sensitive gel layer 2a. That is to say, the bonding surface 21b of the adhesive layer 2b is approximately parallel to the first board surface 11 or the second board surface 12. Moreover, the adhesive layer 2b seamlessly covers the predetermined portion of the first board surface 11 of the circuit board 1 and the conductive circuit 13.

In step e), as shown in FIG. 13, the periphery fixture 205 and the transparent film 206 are removed, and a release film 3 is flatly and detachably disposed on the bonding surface 21b of the adhesive layer 2b. Specifically, the release film 3 is approximately parallel to the first board surface 11 or the second board surface 12, and the release film 3 is entirely adhered to the bonding surface 21b of the adhesive layer 2b. In such a manner the circuit board structure 100 is prepared by the above steps of the method.

### The Possible Effect of the Instant Disclosure

In summary, the method of the instant disclosure is directly and integrally forming the adhesive layer on the circuit board, so a single manufacturer can independently produce the circuit board structure without the conventional adhering step and the conventional cutting step of the double sided tape, thereby effectively reducing the producing cost of the circuit board structure.

Moreover, the pressure-sensitive gel layer is seamlessly formed on the board surface of the circuit board, so no gap exists between the adhesive layer and the circuit board, and the adhesion strength of the adhesive layer and the circuit board can be increased by the roughness of the board surface of the circuit board.

In addition, the method of the instant disclosure is directly and integrally forming the adhesive layer on the circuit board to obtain the planar bonding surface, thereby increasing the adhering force of the adhesive layer.

The descriptions illustrated supra set forth simply the preferred embodiments of the instant invention; however, the characteristics of the instant invention are by no means restricted thereto. All changes, alterations, or modifications conveniently considered by those skilled in the art are deemed to be encompassed within the scope of the instant invention delineated by the following claims.

What is claimed is:

1. A method for manufacturing a circuit board structure, comprising:
a) providing a circuit board, wherein the circuit board has a first board surface and an opposite second board surface, the first board surface defines a predetermined portion;
b) disposing the circuit board in a production apparatus;
c) screen printing a pressure-sensitive gel on the predetermined portion of the circuit board to form a pressure-sensitive gel layer by using the production apparatus, wherein a thickness of the pressure-sensitive gel layer is 30 μm-350 μm; and
d) solidifying the pressure-sensitive gel layer to form an adhesive layer seamlessly covering the predetermined portion of the circuit board by using the production apparatus, wherein a surface of the adhesive layer arranged away from the circuit board is defined as a bonding surface.

2. The method as claimed in claim 1, wherein the pressure-sensitive gel layer is a UV-curable pressure-sensitive gel layer; the method further comprises:
in the step d), solidifying the pressure-sensitive gel layer to form the adhesive layer by using UV light emitted from the production apparatus; and
after the step d), disposing a release film on the bonding surface of the adhesive layer.

3. The method as claimed in claim 1, wherein the pressure-sensitive gel layer is a UV-curable pressure-sensitive gel layer; the method further comprises:
after the step c), disposing a transparent release film on a surface of the pressure-sensitive gel layer arranged away from the circuit board; and
in the step d), solidifying the pressure-sensitive gel layer to form the adhesive layer by using UV light emitted from the production apparatus to pass through the transparent release film.

4. The method as claimed in claim 2, wherein the step d) further comprises:
disposing the circuit board and the pressure-sensitive gel layer into a translucent chamber of the production apparatus;
filling or blowing nitrogen into the chamber by using the production apparatus; and
solidifying the pressure-sensitive gel layer to form the adhesive layer by using UV light to pass through the chamber.

5. The method as claimed in claim 1, further comprising:
in the step b), disposing a periphery fixture on the first board surface, wherein the periphery fixture has a penetrating hole aligning with the predetermined portion of the first board surface;
in the step c), filling the pressure-sensitive gel into the penetrating hole of the periphery fixture by screen printing; and
in the step d), disposing a transparent film on the pressure-sensitive gel layer and the periphery fixture, and solidifying the pressure-sensitive gel layer to form the adhesive layer by using UV light to pass through the transparent film

6. The method as claimed in claim 1, wherein the pressure-sensitive gel layer is made of acrylic, acrylates, silicone prepolymer, silicone monomer, or a mixture of silicone prepolymer and silicone monomer.

7. The method as claimed in claim 1, wherein the circuit board is a flexible circuit board or a rigid-flex circuit board, the circuit board has a conductive circuit disposed on the first board surface, and at least part of the conductive circuit is disposed on the predetermined portion and embedded in the pressure-sensitive gel layer, and a surface of the pressure-sensitive gel layer arranged away from the circuit board is a plane.

8. A circuit board structure is prepared by implementing the method as claimed in claim 1.

9. A circuit board structure, comprising:
a circuit board having a first board surface and an opposite second board surface, wherein the first board surface defines a predetermined portion, the circuit board has a conductive circuit disposed on the first board surface, and at least part of the conductive circuit is disposed on the predetermined portion; and
an adhesive layer seamlessly formed on the predetermined portion of the first board surface of the circuit board, wherein the adhesive layer seamlessly covers the at least part of the conductive circuit, and a surface of the adhesive layer arranged away from the circuit board is a planar bonding surface.

10. The circuit board structure as claimed in claim 9, wherein the adhesive layer is made of acrylic, acrylates, silicone prepolymer, silicone monomer, or a mixture of silicone prepolymer and silicone monomer, wherein a thickness of the adhesive layer is 100 μm-200 μm.

11. The circuit board structure as claimed in claim 9, further comprising a release film seamlessly and detachably disposed on the bonding surface of the adhesive layer.
